(19) United States
(12) Patent Application Publication
(10) Pub. No.: US 2024/0379404 A1
(43) Pub. Date: Nov. 14, 2024

(54) APPARATUS AND METHOD FOR SUBSTRATE HANDLING

(71) Applicant: Taiwan Semiconductor Manufacturing Company, Ltd., Hsinchu (TW)

(72) Inventors: Jen-Chun Liao, Taipei City (TW); Sung-Yueh Wu, Chiayi County (TW); Chien-Ling Hwang, Hsinchu City (TW); Ching-Hua Hsieh, Hsinchu (TW)

(73) Assignee: Taiwan Semiconductor Manufacturing Company, Ltd., Hsinchu (TW)

(21) Appl. No.: 18/780,534

(22) Filed: Jul. 23, 2024

Related U.S. Application Data
(62) Division of application No. 17/367,631, filed on Jul. 6, 2021.
(60) Provisional application No. 63/168,264, filed on Mar. 31, 2021.

(51) Int. Cl. H01L 21/683; H01L 21/67; H01L 21/687

(52) U.S. Cl. CPC H01L 21/6838; H01L 21/68735; H01L 21/67288

(57) ABSTRACT

A method for handling a semiconductor substrate includes: placing a semiconductor substrate over a semiconductor apparatus, where a central portion of the semiconductor substrate overlies a carrying surface of a chuck table of the semiconductor apparatus, an edge portion of the semiconductor substrate overlies a top surface of a first flexible member of the semiconductor apparatus, the first flexible member is disposed within a recess of the chuck table and extends along a perimeter of the carrying surface, and a gap forms among the semiconductor substrate, the carrying surface of the chuck table, and the top surface of the first flexible member; and introducing a vacuum in vacuum holes in the chuck table to form a vacuum seal among the semiconductor substrate, the chuck table, and the first flexible member.

### CROSS-REFERENCE TO RELATED APPLICATION

This application is a divisional application of and claims the priority benefit of U.S. application Ser. No. 17/367,631, filed on Jul. 6, 2021, now pending. The prior application Ser. No. 17/367,631 claims the priority benefit of U.S. provisional application Ser. No. 63/168,264, filed on Mar. 31, 2021. The entirety of the above-mentioned patent applications is hereby incorporated by reference herein and made a part of this specification.

### BACKGROUND

Most integrated circuits are manufactured on semiconductor substrates by sequentially forming various material layers and structures over previously formed layers and structures. Due to varying coefficients of thermal expansion (CTEs) of different materials, thermal issues during the fabrication process may lead to warpage of the semiconductor substrates. Accordingly, there is continuous effort in developing new mechanisms of controlling warpage behavior to form semiconductor substrates with better performance. Although existing apparatus for handling semiconductor substrates has been generally adequate for its intended purposes, it has not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top-down view of a chuck table of a semiconductor apparatus according to some embodiments.

FIG. 2 is a schematic cross-sectional view of the semiconductor apparatus of FIG. 1 taken along the A-A′ line according to some embodiments.

FIG. 3 is a schematic and partial perspective view of a flexible member according to some embodiments.

FIGS. 4-6 are schematic cross-sectional view showing a warped semiconductor substrate placed over a chuck table of a semiconductor apparatus according to different embodiments.

FIG. 7 is a schematic cross-sectional view showing a semiconductor substrate secured onto a chuck table of a semiconductor apparatus according to some embodiments.

FIGS. 8-10 are schematic cross-sectional views showing various stages of flattening a warped semiconductor substrate on a chuck table of a semiconductor apparatus according to some embodiments.

FIGS. 11-13 and 15 are schematic cross-sectional views showing various chuck tables according to different embodiments.

FIG. 14 is a schematic top-down view of a chuck table shown in FIG. 13 according to some embodiments.

FIG. 16 is a schematic top-down view of a chuck table shown in FIG. 15 according to some embodiments.

FIGS. 17-18 are schematic cross-sectional views showing a warped semiconductor substrate placed on a chuck table according to various embodiments.

FIG. 19 is a schematic cross-sectional view showing a warped semiconductor substrate placed on a dicing tape over a chuck table according to some embodiments.

FIG. 20 is a schematic cross-sectional view a semiconductor substrate placed on a chuck table for performing a measurement process according to some embodiments.

FIG. 21 is a schematic cross-sectional view a semiconductor substrate placed on a chuck table for performing a fabrication process according to some embodiments.

FIG. 22 is a schematic cross-sectional view a semiconductor substrate held by a chuck table for transferring according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are related to semiconductor apparatus and methods for substrate handling, and in particular, the semiconductor apparatus equipped with a flexible member to enhance the vacuum holding of a semiconductor substrate will be described herein. The flexible member serving as a seal ring may be circumferentially positioned on a chuck table and configured to provide maximum sealing capability when a vacuum is applied. Some variations of embodiments are discussed and the intermediate stages of substrate handling are illustrated. It should be appreciated that the illustration throughout the drawings are schematic and various features are arbitrarily drawn in different scales for the sake of simplicity and clarity.

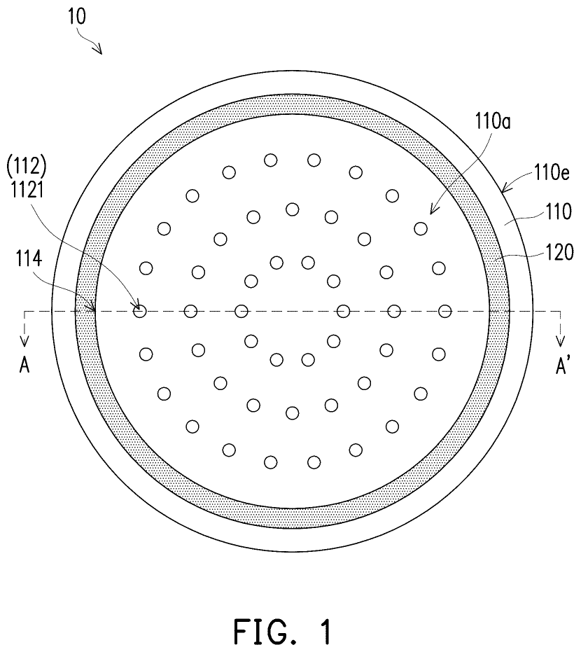

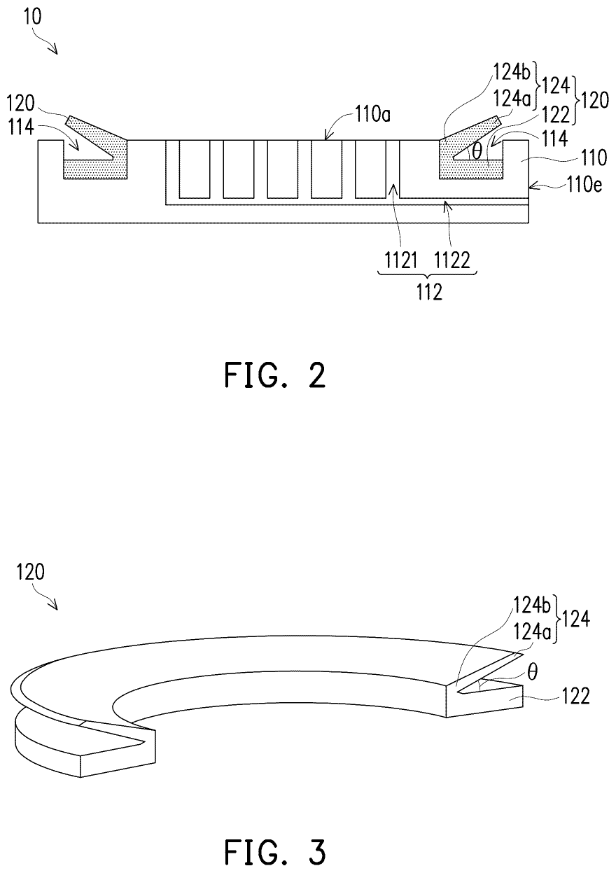

FIG. 1 is a schematic top-down view of a chuck table of a semiconductor apparatus, FIG. 2 is a schematic cross-sectional view of the semiconductor apparatus of FIG. 1 taken along the A-A′ line, and FIG. 3 is a schematic and partial perspective view of a flexible member, in accordance with some embodiments.

Referring to FIGS. 1-2, a semiconductor apparatus 10 is provided. It should be understood that various features of the semiconductor apparatus 10 are not shown for the sake of simplicity and illustration. In some embodiments, the semiconductor apparatus 10 is a substrate holding apparatus that includes a chuck table 110. The chuck table 110 includes a carrying surface 110a that is configured to support a to-be processed semiconductor substrate (not shown) when a vacuum force is applied on the to-be processed semiconductor substrate. For example, the chuck table 110 may have a diameter that is suitable to hold the semiconductor substrate, and the diameter of the chuck table 110 may vary according to the semiconductor substrate.

In some embodiments, the chuck table 110 is provided with a vacuum channel 112 that may include a plurality of holes (or openings) 1121 and a passageway 1122, where the passageway 1122 is in fluid communication with each of the holes 1121. For example, the chuck table 110 may be one single piece with the passageway 1122 directly connecting the holes 1121 in different sites. In some embodiments, the passageway 1122 is disposed below and substantially parallel to the carrying surface 110a, and the respective hole 1121 vertically extends from the carrying surface 110a to the passageway 1122. The end of the passageway 1122 located at the edge 110e of the chuck table 110 may be coupled to a vacuum source (not shown) and may serve as the inlet for introducing vacuum. For example, the passageway 1122 is coupled to a vacuum pump (not individually illustrated). During the operation, the vacuum pump evacuates any gases from the vacuum channel 112, thereby lowering the pressure within the chuck table 110 relative to the ambient pressure. Thus, vacuum may be introduced into the vacuum channel 112 to form a seal between the chuck table 110 and the semiconductor substrate disposed thereon.

In some embodiments, in the top-down view, the holes 1121 are arranged in a periodic pattern such as an array. For example, the holes 1121 are arranged in a concentric circular manner. In some embodiments, the holes 1121 are arranged in radially and substantially equidistant manner across the carrying surface 110a. The holes 1121 may be arranged in a uniform (and/or a non-uniform) group(s). It is understood that although the holes 1121 shown in FIG. 1 all have substantially circular shapes, other embodiments of the holes may take on other shapes, such as a rectangular, oval, triangular, or a polygonal shape, etc. Additionally, the number and the size of the holes 1121 and the number and the size of the passageway 1122 illustrated herein are merely examples and are not limited.

In some embodiments, the chuck table 110 is provided with a recess (or groove) 114 that is between the edge 110e of the chuck table 110 and the array of the holes 1121. In the top-down view, the recess 114 may be of a ring shape and enclose the distribution array of the holes 1121. In some embodiments, the recess 114 has a rectangular cross section as shown in FIG. 2. Although the cross section of the recess 114 may be of any suitable shape. In some embodiments, the recess 114 is configured to accommodate a flexible member 120 that is provided to improve the vacuum seal. For example, the flexible member 120 is configured to form a seal around the array of the holes 1121 when a vacuum force is introduced in the vacuum channel 112. For example, during the operation, the flexible member 120 deforms and contacts with the semiconductor substrate without any gap to avoid vacuum leakage.

The stiffness of the flexible member 120 may be lower than that of the chuck table 110. For example, the material of the flexible member 120 is flexible (or compressible) under a force. In some embodiments, the flexible member 120 is formed of an elastomeric material that is of sufficient diameter to form a pressure seal. The material of the flexible member 120 may be or may include a rubber or a polymer such as high density polyethylene (HDPE), synthetic rubber, phenol formaldehyde resin, nylon, polystyrene, polypropylene, PVB, silicone, a combination thereof, etc. The Young's Modulus of the flexible member 120 may be in a range of about 0.002 GPa and about 0.044 GPa.

Referring to FIG. 3 and with reference to FIGS. 1-2, the cross section of the flexible member 120 may be provided in V-shape (or U-shape). In some embodiments, the flexible member 120 is referred to as a V-shaped seal ring. For example, the flexible member 120 includes a first portion 122 and a second portion 124, where the first portion 122 of the flexible member 120 may be physically engaged with inner surfaces of the chuck table 110 that define the recess 114, and the second portion 124 is connected to the first portion 122. In some embodiments, the second portion 124 of the flexible member 120 includes a free end 124a and a fixed end 124b opposite to the free end 124a, where the fixed end 124b connect the first portion 122 to the free end 124a. In some embodiments, an angle θ forms between the first portion 122 and the second portion 124. The angle θ may be an acute angle. It should be noted that the value of the angle θ may vary depending on the warpage profile of the to-be processed semiconductor substrate and/or process requirements. In some embodiments, deformation may occur and the angle θ may reduce due to compression of the semiconductor substrate during the operation.

The vacuum may be introduced during the operation. This allows air (or other suitable gas) between the semiconductor substrate and the flexible member 120 to be purged. The second portion 124 of the flexible member 120 may be compressed by way of a downward force that is applied by the semiconductor substrate due to the fluid pressure difference. The design of the flexible member 120 may be in various cross-sectional profiles that are adapted for use on the semiconductor substrate having different warpage profiles. In some embodiments, the flexible member 120 is detachably engaged with the surfaces that define the recess 114. The flexible member 120 may be replaced with a flexible member with different design to meet the process requirements or with a new flexible member as it becomes damaged during operation.

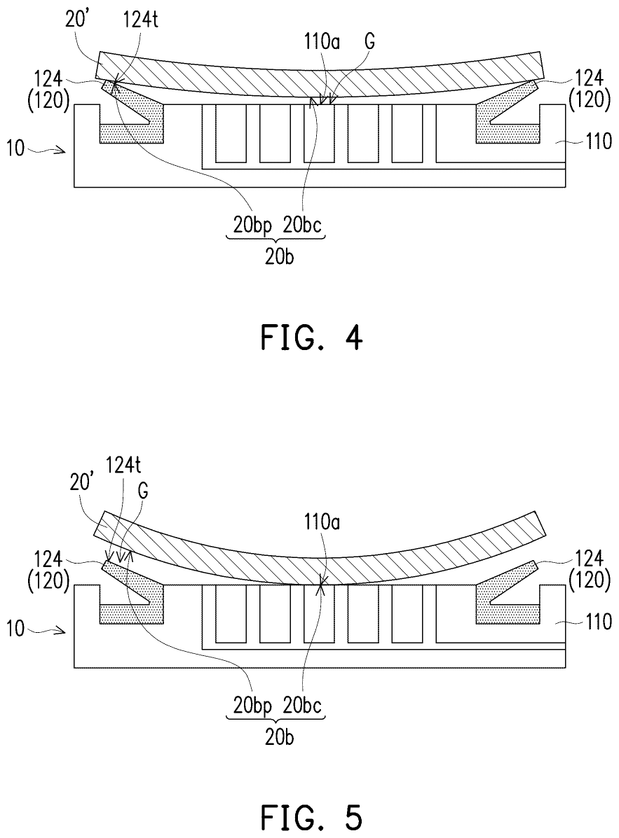

FIGS. 4-6 are schematic cross-sectional view showing a warped semiconductor substrate placed over a chuck table of a semiconductor apparatus according to different embodiments. Throughout the various views and illustrative embodiments, like reference numbers are used to designate like elements. Referring to FIGS. 4-6, a semiconductor substrate 20′ is placed over the chuck table 110 of the semiconductor apparatus 10. The semiconductor substrate 20′ may be referred to as a warped semiconductor substrate. The warpage of the semiconductor substrate 20′ may be caused by a difference in the coefficients of thermal expansion (CTEs) between layers of different materials. For example, the semiconductor substrate 20′ includes various features (not individually illustrated) depending on product requirements.

In some embodiments, the semiconductor substrate 20′ is a single substrate (e.g., a silicon substrate wafer) or a composite substrate having a dielectric layer and/or a conductive layer formed on the silicon substrate. The semiconductor substrate 20′ may be in a wafer form or may be a non-circular form (e.g., a panel form). In some embodiments, the semiconductor substrate 20′ is an unpackaged semiconductor substrate having a plurality of semiconductor devices (e.g., active devices and/or passive devices) formed on the active surface. In some embodiments, the semiconductor substrate 20′ includes a device package with at least one semiconductor die encapsulated by an insulating encapsulation. In some embodiments, the semiconductor substrate 20′ further includes a package substrate having through substrate vias connected to the device package. In some embodiments, the semiconductor substrate 20′ includes a wafer-level package having a carrier with the semiconductor devices and interconnecting packaged to another substrate. It should be understood that the semiconductor substrate 20′ is shown in a simplified manner, and that variations thereof may be carried out while still remaining within the scope of the claims and disclosure.

In some embodiments, the semiconductor substrate 20′ is intrinsically warped to a concave shape with a central portion of the semiconductor substrate 20′ being lower than an edge portion of the semiconductor substrate 20′. It should be noted that the curvature of the semiconductor substrate 20′ may vary and is not limited in the disclosure. In some other embodiments, the semiconductor substrate 20′ has a convex warpage profile. Alternatively, the semiconductor substrate 20′ may present more complex warpages rather than simple convex or simple concave warpages. As shown in FIG. 4, after the semiconductor substrate 20′ is disposed on the chuck table 110, the edge portion of the semiconductor substrate 20′, which is bowed upwardly, may be abutted against the flexible member 120. For example, a part of the top surface 124t of the second portion 124 of the flexible member 120 is in physical contact with the edge portion 20bp of the bottom surface 20b of the semiconductor substrate 20′. The central portion 20bc of the semiconductor substrate 20′ may not be in physical contact with the carrying surface 110a. A gap G may form among the carrying surface 110a of the chuck table 110, the top surface 124t of the flexible member 120, and the bottom surface 20b of the semiconductor substrate 20′.

In some embodiments, as shown in FIG. 5, after placing the semiconductor substrate 20′ on the chuck table 110, the central portion 20bc of the semiconductor substrate 20′, which is lower than the edge portion 20bp of the semiconductor substrate 20′, may be abutted against the carrying surface 110a of the chuck table 110. For example, the edge portion of the semiconductor substrate 20′ is spatially spaced apart from each other, and a gap G forms between the top surface 124t of the second portion 124 of the flexible member 120 and the edge portion 20bp of the bottom surface 20b of the semiconductor substrate 20′.

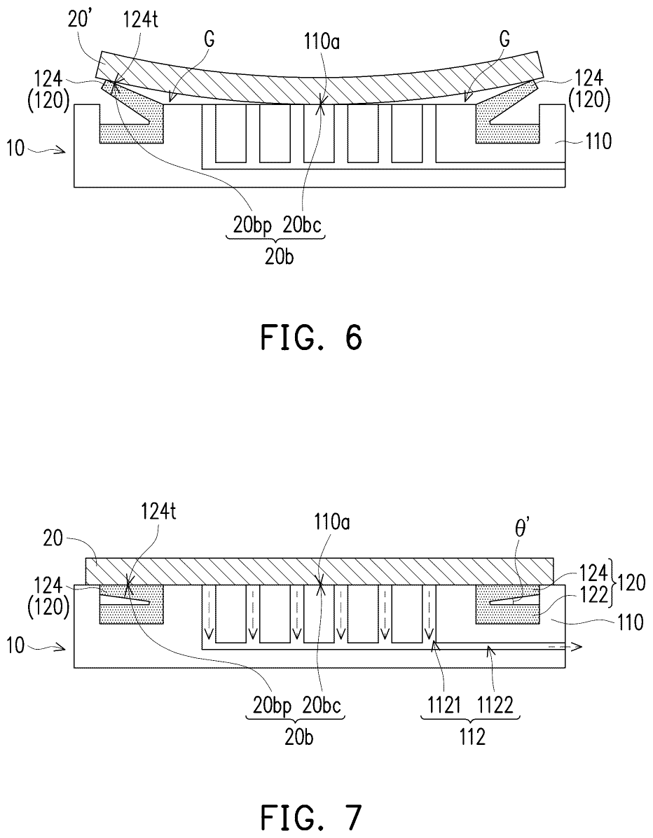

In some embodiments, as shown in FIG. 6, after placing the semiconductor substrate 20′ on the chuck table 110, the edge portion 20bp and the central portion 20bc of the bottom surface 20b of the semiconductor substrate 20′ are respectively in physical contact with the flexible portion 120 and the carrying surface 110a of the chuck table 110. A middle portion of the bottom surface 20b between the edge portion 20bp and the central portion 20bc may be spatially spaced apart from the carrying surface 110a and the top surface 124t of the flexible member 120, and thus the gap G forms therebetween. It should be understood that at this stage, the contact area of the semiconductor substrate 20′ and the chuck table 110 as well as the flexible member 120 may vary depending on the curvature of the to-be processed semiconductor substrate and the angle of the flexible member.

FIG. 7 is a schematic cross-sectional view showing a semiconductor substrate secured onto a chuck table of a semiconductor apparatus according to some embodiments. Referring to FIG. 7 and with reference to FIGS. 4-6, vacuum in the vacuum channel 112 is created to secure the semiconductor substrate 20 onto the chuck table 110 of the semiconductor apparatus 10. For example, after placing the warped semiconductor substrate 20′ on the chuck table 110 (as shown in FIG. 4, 5, or 6), the pressure within the vacuum channel 112 may be reduced by the vacuum pump (not shown). For example, the vacuum pump is used to create a suction force so that fluid (e.g., air or another suitable gas or liquid) is forced to flow out of the holes 1121, through the passageway 1122, toward the vacuum source as indicated by the dashed arrows. In other words, the vacuum pump is supplying a vacuum. The suction force (e.g., air pressure difference) may pull the warped semiconductor substrate against the carrying surface 110a in a downward direction. In some embodiments, a control unit (not shown; e.g., valves, pumps, sensors, etc.) of the semiconductor apparatus 10 is coupled to the vacuum channel 112 in a way that the control unit may control independently or collectively the pressure in the holes 1121 of the vacuum channel 112. In some embodiments, the control unit of the semiconductor apparatus 10 is configured to selectively vary the pressure in each of the holes 1121 in order to adjust the amount of warpage of the semiconductor substrate.

With the pressure continually lowered within the vacuum channel 112, the warped semiconductor substrate may be bent downwardly to achieve a substantially flat semiconductor substrate 20. In some embodiments, the vacuum created in the vacuum channel 112 forced the warped semiconductor substrate against the flexible member 120. The second portion 124 of the flexible member 120 may be compressed in conformance with the edge portion 20bp of the semiconductor substrate 20 as the semiconductor substrate is substantially flattened. For example, the bottom surface 20b of the semiconductor substrate 20 is physically attached to the entire carrying surface 110a and the entire top surface 124t of the flexible member 120. Therefore, the flexible member 120 and the semiconductor substrate 20 form a seal to avoid vacuum leakage and prevent the semiconductor substrate 20 from moving during the subsequent operation(s).

As shown in FIGS. 4 and 7, after placing the semiconductor substrate 20′ over the chuck table 110, the vacuum is then created in the holes 1121 and passageway 1122. The vacuum applies a force to pull the semiconductor substrate 20′ against the chuck table 110, and thus the central portion 20bc of the bottom surface 20b of the semiconductor substrate 20′ may be in direct contact with the carrying surface 110a of the chuck table 110. This allows the semiconductor substrate 20′ to be held onto the chuck table 110. A downward force that is applied to the semiconductor substrate 20′ due to the pressure difference causes the flexible member 120 being pressed by the edge portion 20bp of the semiconductor substrate 20′. This allows the second portion 124 of the flexible member 120 to be moved downward, and the angle θ between the first portion 122 and the second portion 124 is thus reduced to an angle θ′. In some embodiments, the top surface 124t of the second portion 124 of the flexible member 120 is substantially leveled (e.g., coplanar) with the carrying surface 110a of the chuck table 110. The gap G among the bottom surface 20b of the semiconductor substrate 20′, the carrying surface 110a of the chuck table 110, and the top surface 124t of the flexible member 120 may be eliminated to form a seal.

In some embodiments as shown in FIGS. 5 and 7, when the semiconductor substrate 20′ is placed over the chuck table 110, only a part of the central portion 20bc of the semiconductor substrate 20′ is in contact with the carrying surface 110a. During the operation of introducing the vacuum force on the semiconductor substrate 20′, a suction force may pull the edge portion 20bp of the semiconductor substrate 20′ downwardly to be in physical contact with the flexible member 120, and the flexible member 120 may further be pressed until the gap G among the semiconductor substrate 20′, the chuck table 110, the flexible member 120 is removed to achieve a substantially flat semiconductor substrate 20. In some embodiments as shown in FIGS. 6 and 7, when the semiconductor substrate 20′ is placed over the chuck table 110, a part of the central portion 20bc of the semiconductor substrate 20′ is in contact with the carrying surface 110a and a part of the edge portion 20bp of the semiconductor substrate 20′ is in contact with the second portion 124 of the flexible member 120. Next, the pressure in the holes 1121 may be reduced to cause a vacuum effect inside the vacuum channel 112, which results in a suction force that bents the semiconductor substrate 20′ downwardly to achieve a substantially flat semiconductor substrate 20.

In some embodiments, after flattening the semiconductor substrate 20, a subsequent process (e.g., measurement, lithography, singulation, etc.) is then performed. It is understood that the subsequent processes may be sensitive to flatness, and the semiconductor substrate that is not substantially flat will complicate subsequent fabrication and test processes which may adversely affect the manufacture yield. The flexible member 120 situated on the chuck table 110 may be provided to forms a seal around the holes 1121 when the vacuum is introduced in the vacuum channel 112, thereby avoiding vacuum leakage at the edge of the semiconductor substrate.

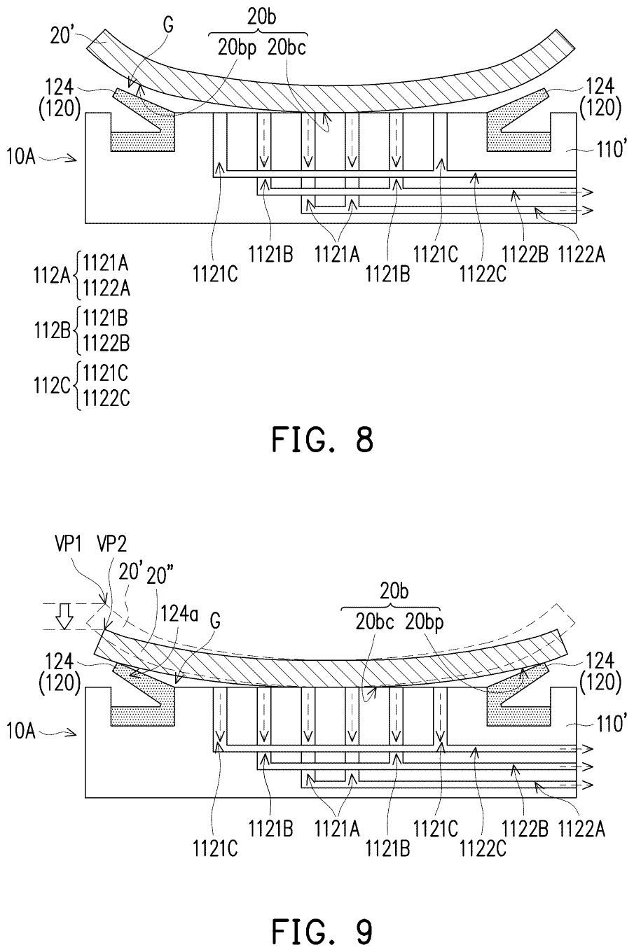

FIGS. 8-10 are schematic cross-sectional views showing various stages of flattening a warped semiconductor substrate on a chuck table of a semiconductor apparatus according to some embodiments. Throughout the various views and illustrative embodiments, like reference numbers are used to designate like elements. Referring to FIG. 8, the semiconductor substrate 20′, which is warped upwardly, is placed over a chuck table 110′ of a semiconductor apparatus 10A. In some embodiments, only a part of the central portion 20bc of the semiconductor substrate 20′ is in physical contact with the chuck table 110′, and the gap G is formed between the flexible member 120 and the edge portion 20bp of the semiconductor substrate 20′. In some embodiments, only a part of the edge portion 20bp of the semiconductor substrate 20′ is in physical contact with the second portion 124 of the flexible member 120, and the gap G is formed between the carrying surface 110a and the semiconductor substrate 20′, as described in FIG. 4. In some embodiments, a part of the central portion 20bc and a part of the edge portion 20bp of the semiconductor substrate 20′ are respectively in physical contact with the carrying surface 110a and the flexible member 120, as described in FIG. 6.

The semiconductor apparatus 10A may be similar to the semiconductor apparatus 10 discussed in the preceding paragraphs, except that the chuck table 110′ of the semiconductor apparatus 10A is provided with multiple vacuum channels (e.g., 112A, 112B, and 112C). Each of the vacuum channels (112A, 112B, and 112C) may include at least one hole (e.g., 1121A, 1121B, or 1121C) and the passageway (e.g., 1122A, 1122B, or 1122C) connected to the corresponding hole(s). For example, the holes 1121A are arranged in the innermost zone corresponding to the central portion, the holes 1122C are arranged in the outermost zone surrounding the innermost zone, and the holes 1122B are arranged in the middle zone between the innermost zone and the outermost zone. In some embodiments, the vacuum channels (112A, 112B, and 112C) are individually segregated from one another. It should be noted that three sets of the vacuum channels are shown for illustrative purposes, and two sets or more than three sets of the vacuum channels may be employed depending on process requirements.

After placing the semiconductor substrate 20′ on the chuck table 110, the gas in the vacuum channels (112A, 112B, and 112C) may be evacuated through the vacuum pump (not shown), and the gas may be forced to flow out of the holes (1121A, 1121B, or 1121C), through the passageway (1122A, 1122B, or 1122C), toward the vacuum source as indicated by the dashed arrows. The suction force is thus created to pull the semiconductor substrate 20′ against the chuck table 110′. In some embodiments, the gas in the respective vacuum channel (112A, 112B, and 112C) is evacuated at the same time. Alternatively, the gas in the vacuum channels (112A, 112B, and 112C) is independently and selectively evacuated so that varying pressure is in the vacuum channels. In some embodiments in which the semiconductor substrate 20′ has the concave warpage profile, the vacuum applies the suction force to pull the semiconductor substrate 20′ against the chuck table 110′ so that the distance between the bottom surface 20b and the carrying surface 110a in the gap G may gradually decrease, thereby forming the vacuum seal in each zone. For example, as shown in FIG. 8, the vacuum seal is first formed in the innermost zone. At this stage, the vacuum seal may not be formed at the middle zone, the outermost zone, and the peripheral region where the flexible member is located on.

Referring to FIG. 9 and with reference to FIG. 8, as the downward force is continuously applied to the semiconductor substrate 20′, the amount of warpage of the semiconductor substrate 20′ gradually decreases to form the semiconductor substrate 20″. Additionally, the gap G may be gradually reduced. For example, the semiconductor substrate 20′ remains secured by the vacuum created in the holes 1121A and the passageway 1122A of the vacuum channel 112A, and the gas in the rest of vacuum channels (112B and 112C) is flowed out to continuously pull the semiconductor substrate 20′ against the chuck table 110′. Subsequently, a seal may be formed at the middle zone where the vacuum is created in the holes 1121B and the passageway 1122B of the vacuum channel 112B. In some embodiments, a part of the edge portion 20bp of the semiconductor substrate 20″ may be in physical contact with a part of the top surface 124t of the second portion 124 of the flexible member 120 at this stage.

As shown in FIG. 9, the vacuum seal may be formed at the innermost zone and the middle zone. At this stage, the vacuum seal may not be formed at the outermost zone and the peripheral region where the flexible member 120 is located on. In some embodiments, the vertex point VP1 of the semiconductor substrate 20′ is lowering down to reach the vertex point VP2 of the semiconductor substrate 20″, where the intersection point of the top surface and the sidewall of the semiconductor substrate is viewed as the vertex point of the semiconductor substrate. The distance between the vertex points VP1 and VP2 is viewed as the reduced amount of the warpage and is not limited in the disclosure.

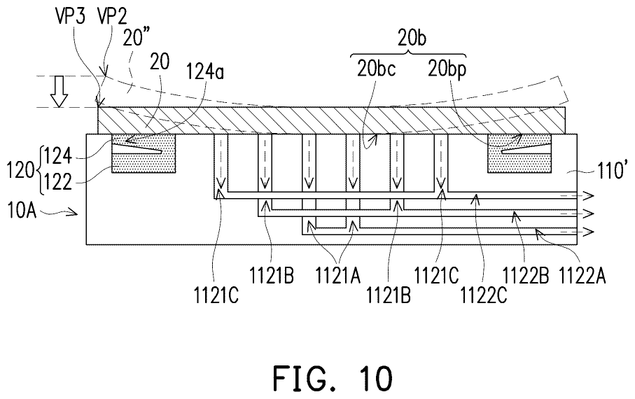

Referring to FIG. 10 and with reference to FIG. 9, the downward force is continuously applied to the semiconductor substrate 20″ to form a substantially flat semiconductor substrate 20 as the gas is evacuated from the vacuum channel 112C. The gap G may be eliminated as the vacuum seal is formed among the semiconductor substrate 20, the chuck table 110, and the flexible member 120. For example, the semiconductor substrate 20″ remains secured by the vacuum created in the vacuum channels (112A and 112B), and then a seal may be formed at the outermost zone where the vacuum is created in the holes 1121C and the passageway 1122C of the vacuum channel 112C. The suction force pulls the semiconductor substrate 20″, thereby flattening the semiconductor substrate 20″. For example, the vertex point VP2 of the semiconductor substrate 20″ is lowering down to reach the vertex point VP3 of the semiconductor substrate 20, where the distance between the vertex points VP2 and VP3 is the reduced amount of the warpage and is not limited. Meanwhile, the semiconductor substrate 20 may contact with and press against the flexible member 120 without the gap. The second portion 124 of the flexible member 120 is compressed as the semiconductor substrate 20 presses against the flexible member 120, and the angle between the first portion 122 and the second portion 124 of the flexible member 120 is reduced. Accordingly, the vacuum seal is formed between the edge portion 20bp of the semiconductor substrate 20 and the flexible member 120.

As stated previously, warpage of the semiconductor substrate, especially to the semiconductor substrate with ultra-high warpage, is a consideration, because the subsequent processes may be sensitive to substrate flatness. By using the chuck table 110′ equipped with the vacuum channels (112A, 112B, and 112C) that are individually segregated from one another, the contact area between the semiconductor substrate and the carrying surface 110a starts from a center region of the carrying surface 110a and spreads to a peripheral region of the carrying surface 110a in a radial fashion, as the vacuum force is introduced in the vacuum channels. The amount of warpage of the semiconductor substrate may gradually decrease to achieve a substantially flat semiconductor substrate, and the edge portion of the semiconductor substrate may presses against the flexible member 120, thereby forming a seal to avoid vacuum leakage.

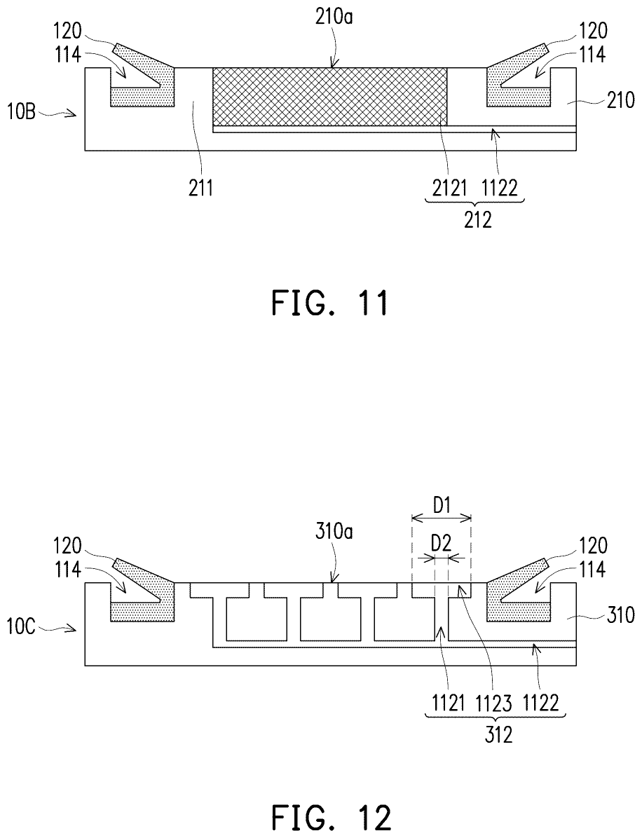

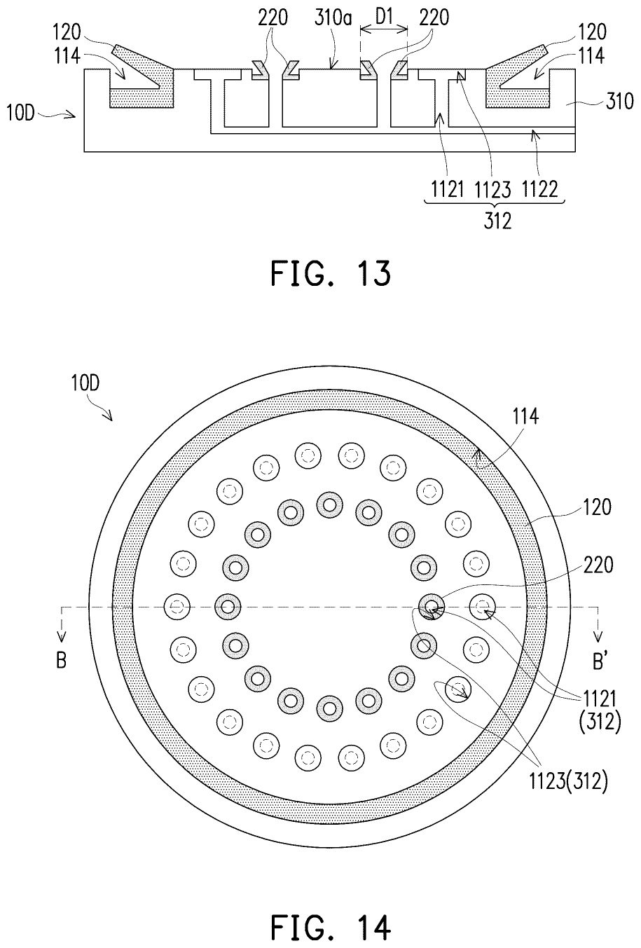

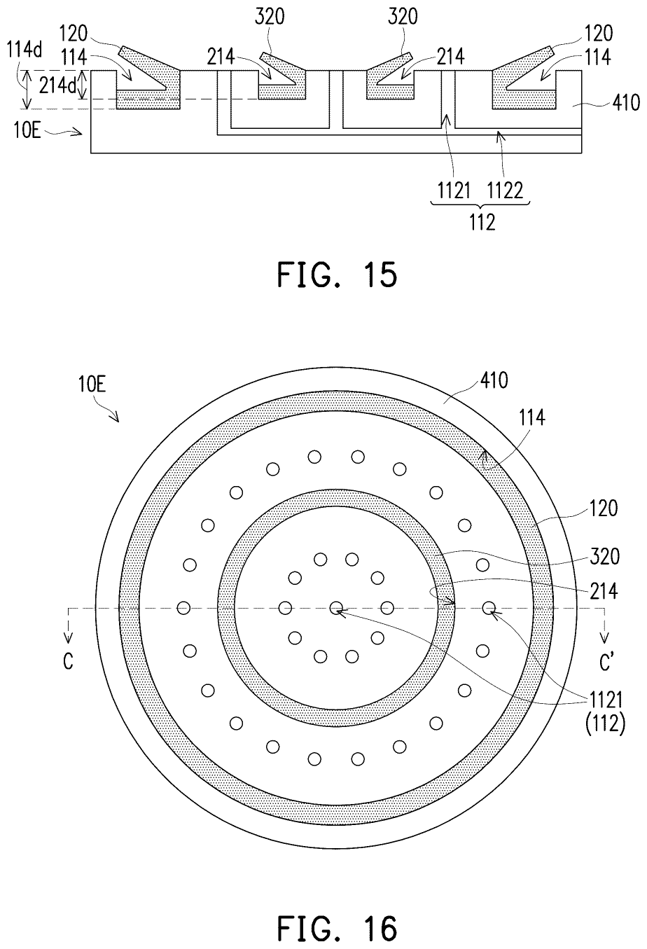

FIGS. 11-12 are schematic cross-sectional views showing various chuck tables according to different embodiments, FIG. 14 is a schematic top-down view of a chuck table, FIG. 13 is a schematic cross-sectional view of the chuck table of FIG. 14 taken along the B-B′ line, and FIG. 16 is a schematic top-down view of a chuck table, FIG. 15 is a schematic cross-sectional view of the chuck table of FIG. 16 taken along the C-C′ line, in accordance with some embodiments. Throughout the various views and illustrative embodiments, like reference numbers are used to designate like elements. It should be noted that the variations discussed below are merely examples, and the number, the size, the shape, and the configuration of various features (e.g., holes, slot openings, flexible members, etc.) are not limited in the disclosure.

Referring to FIG. 11, a semiconductor apparatus 10B includes a chuck table 210 and the flexible member 120 mounted onto the periphery of the chuck table 210. In some embodiments, the chuck table 210 includes a base 211 equipped with a vacuum module 212 and the recess 114. The recess 114 is configured to accommodate the flexible member 120 as described in the preceding paragraphs. The vacuum module 212 may include a porous structure 2121 embedded in the base 211, and the passageway 1122 of the vacuum module 212 is embedded in the base 211 and in fluid communication with the porous structure 2121. The base 211 may be made of a non-porous material, which by itself does not allow gas to penetrate if there is no hole. The porous structure 2121 may be formed of a porous (permeable) material such as a porous ceramic, which includes pores therein, so that gas may penetrate through the pores in the porous structure 2121. The top surface of the porous structure 2121 may serve as the carrying surface 210a that is configured to support the to-be processed semiconductor substrate. The bottom of the porous structure 2121 may be coupled to the passageway. During the operation, the gas may be forced to flow out of the porous structure 2121, through the passageway 1122 toward a vacuum source (e.g., a vacuum pump).

Referring to FIG. 12, a semiconductor apparatus 10C including a chuck table 310 and the flexible member 120 is similar to the semiconductor apparatus 10 shown in FIG. 2, except for the design of a vacuum channel 312 of a chuck table 310. The flexible member 120 may be disposed in the recess 114 along the perimeter of the chuck table 310. In some embodiments, the vacuum channel 312 of the chuck table 310 includes a plurality of slot openings 1123 recessed from the carrying surface 310a, and the holes 1121 connect the slot openings 1123 to the passageway 1122. In some embodiments, each of the holes 1121 is connected to one of the slot openings 1123. For example, the opening diameter D1 of the respective slot opening 1123 is substantially greater than the opening diameter D2 of the corresponding hole 1121. The slot openings 1123 may have substantially the same opening diameter D1. Alternatively, the slot openings 1123 may have various opening diameters. In some embodiments, the slot openings 1123 are discontinuous and segregated from one another in a top-down view. For example, the respective slot opening 1123 having a circular top-view shape is in communication with the corresponding hole 1121 (e.g., shown in FIG. 14). Alternatively, the slot openings forming as continuous loops are arranged in a concentric circular manner. It should be understood that the modification of the vacuum channel having individually segregated channels (e.g., shown in FIG. 8) is within the contemplated scope of the disclosure.

Referring to FIGS. 13-14, a semiconductor apparatus 10D including the chuck table 310 and the flexible member 120 is similar to the semiconductor apparatus 10C shown in FIG. 12, except that the semiconductor apparatus 10D further includes additional flexible member(s) 220 disposed within at least one of the slot openings 1123. The inner diameter of the respective flexible member 220 is selected to fit the opening diameter D1 of the corresponding slot opening 1123 without blocking the corresponding hole 1121. In some embodiments, the slot openings 1123 have substantially the same opening diameter D1. In some other embodiments, those slot openings 1123 that are configured to accommodate the flexible members 220 have the opening diameter greater than (or less than) the opening diameter of the rest of the slot openings 1123. The material of the flexible members 220 may be the same as (or similar to) that of the flexible member 120. In some embodiments, the flexible members (120 and 220) are of the same shape but have different inner diameters. Alternatively, the flexible members (120 and 220) are different types of seal rings and have different cross-sections.

In some embodiments where the slot openings 1123 are arranged along the concentric circulars, the flexible members 220 are disposed in those slot openings 1123 arranged in the innermost loop. Alternatively, the flexible members 220 are disposed in those slot openings 1123 arranged in the outermost loop. In some embodiments, each of the flexible members 220 is disposed within one of the slot openings 1123. The flexible members 220 may be disposed within the slot openings 1123 depending on the warpage profile of the to-be processed semiconductor substrate. It should be understood that the modification of the vacuum channel having individually segregated channels (e.g., shown in FIG. 8) is within the contemplated scope of the disclosure.

Referring to FIGS. 15-16, a semiconductor apparatus 10E including a chuck table 410, the flexible member 120, and the additional flexible member 320 is similar to the semiconductor apparatus 10 shown in FIG. 2 (or the semiconductor apparatus 10D shown in FIG. 13). For example, the chuck table 410 of the semiconductor apparatus 10E includes the recess 114 at the outer region and another recess 214 at the inner region. As shown in the top-down view of FIG. 16, the recess 114 and the recess 214 are of a ring shape respectively disposed at the outer region and the inner region of the chuck table 410. In some embodiments, the depth 114d of the recess 114 at the outer region is substantially greater than the depth 214d of the recess 214 at the inner region. Alternatively, the depths of the recesses at the outer/inner regions are substantially the same, or the recess at the inner region may be greater than that of the recess outer region.

In some embodiments, the inner diameter of the flexible member 120 disposed in the recess 114 at the outer region is greater than that of the flexible member 320 disposed in the recess 214 at the inner region. For example, the flexible member 320 disposed in the recess 214 at the inner region surrounds a portion of the holes 1121 distributed in the central region, and another portion of the holes 1121 is arranged between the flexible members (120 and 320) and may be arranged along the perimeter of the flexible member 320. It should be understood that the modification of the vacuum channel having individually segregated channels (e.g., shown in FIG. 8) is within the contemplated scope of the disclosure.

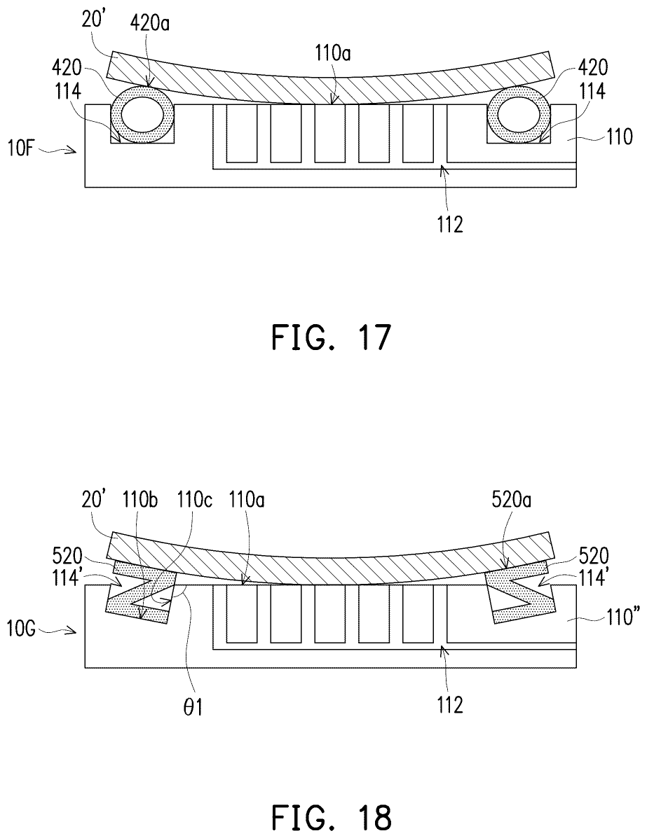

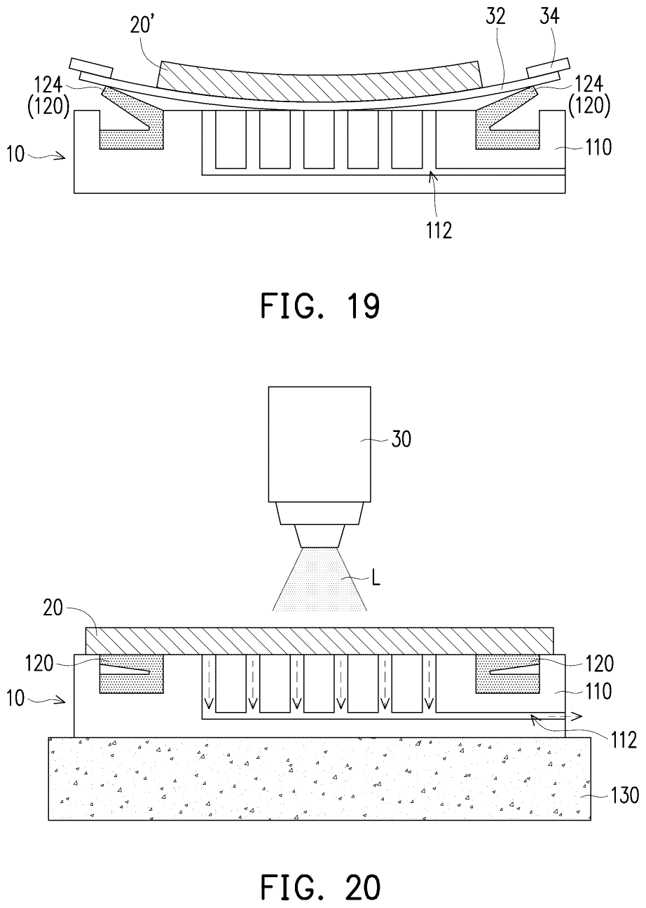

FIGS. 17-18 are schematic cross-sectional views showing a warped semiconductor substrate placed on a chuck table, and FIG. 19 is a schematic cross-sectional view showing a warped semiconductor substrate placed on a dicing tape over a chuck table, in accordance with some embodiments. Throughout the various views and illustrative embodiments, like reference numbers are used to designate like elements. It should be understood that the vacuum channel shown in FIGS. 17-19 is similar to the vacuum channel described in FIG. 2 but it can be replaced with the vacuum channel having individually segregated channels as shown in FIG. 8.

Referring to FIG. 17, a semiconductor apparatus 10F including the chuck table 110 and a flexible member 420 disposed in the recess 114 is provided, and the semiconductor substrate 20′ having a concave warpage profile is placed over the chuck table 110. In some embodiments, the semiconductor substrate 20′ partially contacts the carrying surface 110a of the chuck table 110. In some embodiments, the top surface 420a of the flexible member 420 is protruded from (or higher than) the carrying surface 110a of the chuck table 110 at the initial condition. The edge portion of the semiconductor substrate 20′ may (or may not) be abutted against a portion of the top surface 420a of the flexible member 420 before the vacuum is initiated. The flexible member 420 may be of an elastomeric material that is of sufficient diameter to form a seal.

In some embodiments, the flexible member 420 has an O-shaped cross section and may be referred to as an O-shaped seal ring (or O-ring). For example, the O-shaped seal ring may be hollow or solid depending on process requirements. In some embodiments, during the operation, vacuum is introduced into the vacuum channel 112, and the downward force may pull the semiconductor substrate 20′ against the carrying surface 110a. Meanwhile, the edge portion of the semiconductor substrate 20′ may contact with and press against the flexible member 420, and the flexible member 420 is thus compressed and squeezed, thereby forming a vacuum seal between the flexible member 420 and the semiconductor substrate. In some embodiments, as the vacuum seal is formed, the top surface 420a of the flexible member 420 and the carrying surface 110a of the chuck table 110 may be substantially leveled (e.g., coplanar) with each other.

Referring to FIG. 18, the semiconductor substrate 20′ is placed over a chuck table 110″ of a semiconductor apparatus 10G. The semiconductor apparatus 10G may be similar to the semiconductor apparatus 10F, except that the chuck table 110″ is equipped with a slanted recess 114′ and a flexible member 520 is disposed within the slanted recess 114′. For example, the bottom surface 110b and the sidewall 110c of the chuck table 110″ define the slanted recess 114′, where the inner sidewall 110c and the carrying surface 110a are connected and have an obtuse angle θ1 therebetween, and the bottom surface 110b connected to the inner sidewall 110c is not parallel to the carrying surface 110a.

In some embodiments, the flexible member 520 has an S-shaped or Z-shaped cross section and may be of an elastomeric material that is of sufficient diameter to form a seal. The flexible member 520 may be replaced with other type of flexible member discussed elsewhere in the disclosure. The semiconductor substrate 20′ may be abutted against at least portion of the top surface 520a of the flexible member 520 that is higher than the carrying surface 110a. During the operation, the edge portion of the semiconductor substrate 20′ may press against the flexible member 520 while the suction force is applied to the semiconductor substrate 20′. The flexible member 520 is thus compressed, thereby forming a vacuum seal therebetween. In some embodiments, when the vacuum seal is formed, the top surface 520a of the flexible member 520 and the carrying surface 110a of the chuck table 110 may be substantially aligned (e.g., coplanar) with each other.

Referring to FIG. 19, the semiconductor substrate 20′ mounted on a dicing tape 32 is placed over the chuck table 110 of the semiconductor apparatus 10. The semiconductor apparatus 10 is similar to the semiconductor apparatus 10 described in FIGS. 1-2, so the details thereof are omitted for the sake of brevity. The dicing tape 32 is fixed to a dicing frame 34, and the semiconductor substrate 20′ may be adhered to the dicing tape 32 for subsequent processes. For example, the semiconductor substrate 20′ including a plurality of die regions (or package regions) is mounted on the dicing tape for singulation, measurement, and/or other process. In some embodiments, after the dicing tape 32 with the semiconductor substrate 20′ is placed on the chuck table 110 of the semiconductor apparatus 10, the dicing tape 32 and the dicing frame 34 disposed thereon may be abutted against the second portion 124 of the flexible member 120. During the vacuum is introduced in the vacuum channel 112, the second portion 124 of the flexible member 120 may be compressed in conformance with the dicing tape 32 as the dicing tape 32 is under a downward force.

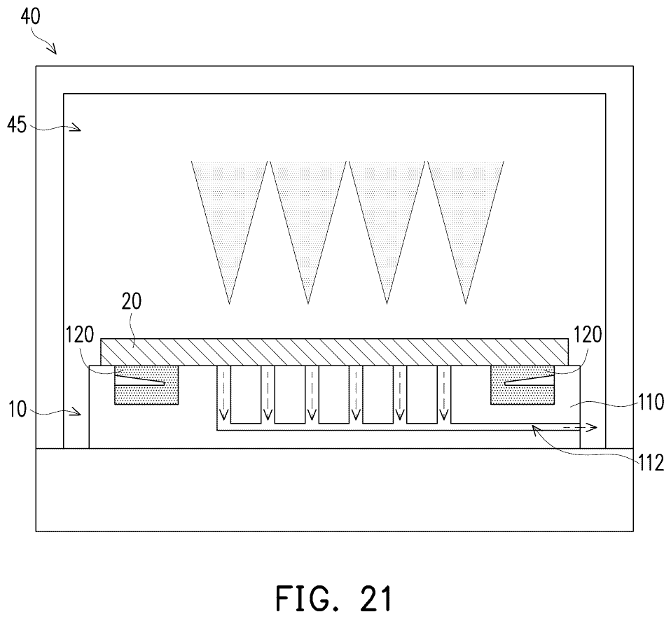

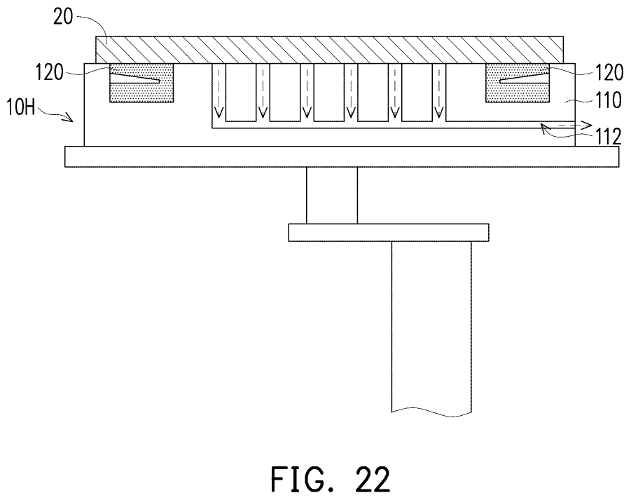

FIG. 20 is a schematic cross-sectional view a semiconductor substrate placed on a chuck table for performing a measurement process, FIG. 21 is a schematic cross-sectional view a semiconductor substrate placed on a chuck table for performing a fabrication process, and FIG. 22 is a schematic cross-sectional view a semiconductor substrate held by a chuck table for transferring, in accordance with some embodiments. Throughout the various views and illustrative embodiments, like reference numbers are used to designate like elements. It should be noted that in FIGS. 20-22, the illustrated semiconductor apparatus that prevents vacuum leaking during handling or manufacturing processes is merely an example and may be replaced with any one of semiconductor apparatus discussed in the preceding paragraphs.

Referring to FIG. 20, the semiconductor apparatus 10 includes a platform 130 and the chuck table 110 disposed on the platform 130. In some embodiments, the platform 130 is configured to drive the semiconductor substrate on the chuck table to move in translational and/or rotational manners during various operations. For example, the semiconductor substrate 20 is secured to the chuck table 110 of the semiconductor apparatus 10 as the vacuum force is introduced in the vacuum channel 112. A metrology tool 30 disposed above the chuck table 110 is configured to perform a measurement process onto the semiconductor substrate 20. In some embodiments, the measurement process may involve projecting a light beam L from the metrology tool 30 to the semiconductor substrate 20 and performing the measurement based on the reflected light, and the measurement may be controlled by processing unit, which may be a computer (not shown). In some embodiments, the measurement process may involve using an infrared energy to check the alignment of bonding for overlay control. It is understood that warping of the semiconductor substrate may lead to overlay issues and measurement errors. The relatively flat semiconductor substrate 20 may be securely attached to the chuck table 110, and the flexible member 120 and the semiconductor substrate 20 form a seal to avoid vacuum leakage as stated previously, those overlay issues and measurement errors may be eliminated.

Referring to FIG. 21, a process tool 40 includes a process chamber 45, and the semiconductor apparatus 10 including the chuck table 110 is disposed within the process chamber 45. The to-be processed semiconductor substrate may be transferred into the process chamber 45 and placed over the chuck table 110. It is understood that the processing of the semiconductor substrate may require holding the semiconductor substrate with the chuck table. For example, the semiconductor substrate 20 may be securely mounted on the chuck table 110 in a similarly fashion as described in the preceding paragraphs. In some embodiments, as the vacuum is introduced in the vacuum channel 112, the semiconductor substrate 20 may be substantially flattened when the semiconductor substrate 20 is under the suction force. The vacuum seal is formed between the semiconductor substrate 20 and the chuck table 110 and between the semiconductor substrate 20 and the flexible member 120. After placing the semiconductor substrate 20 over the chuck table, various processes may be performed onto the semiconductor substrate 20 in the process chamber 45. Those processes (e.g., lithography, patterning, singulation, etc.) may be sensitive to flatness of the semiconductor substrate. By configuring the semiconductor substrate on the chuck table and the flexible member to form improved vacuum seal, manufacturing defects that may adversely affect the yield may be eliminated.

Referring to FIG. 22, the semiconductor substrate 20 is held by a semiconductor apparatus 10H. For example, the semiconductor apparatus 10H is a substrate holding apparatus with a robotic arm, and the substrate holding apparatus is configured to handle substrates in a semiconductor fabrication facility. In some embodiments, the semiconductor apparatus 10H is a part of a pick-up tool that utilizes vacuum for contacting and holding substrates, and the to-be processed semiconductor substrate may be picked-up by the substrate pick-up tool for loading (or unloading) into (or from) a wafer cassette to a process chamber for processing (or transferring between process tools). For example, a vacuum is applied to the vacuum channel 112 to secure the semiconductor substrate 20 to the chuck table 110 and the flexible member 120. A seal is formed between the semiconductor substrate 20 and the chuck table 110 and between the semiconductor substrate 20 and the flexible member 120 to prevent the semiconductor substrate 20 from moving during the various operations of the tooling.

In accordance with some embodiments, a method for handling a semiconductor substrate includes: placing a semiconductor substrate over a semiconductor apparatus, where a central portion of the semiconductor substrate overlies a carrying surface of a chuck table of the semiconductor apparatus, an edge portion of the semiconductor substrate overlies a top surface of a first flexible member of the semiconductor apparatus, the first flexible member is disposed within a recess of the chuck table and extends along a perimeter of the carrying surface, and a gap forms among the semiconductor substrate, the carrying surface of the chuck table, and the top surface of the first flexible member; and introducing a vacuum in vacuum holes in the chuck table to form a vacuum seal among the semiconductor substrate, the chuck table, and the first flexible member.

In accordance with some embodiments, method for handling a semiconductor substrate includes: placing a semiconductor substrate over a carrying surface of a chuck table of a semiconductor apparatus, where the semiconductor apparatus comprises the chuck table comprising vacuum holes extending from the carrying surface, and a flexible member extending along a periphery of the chuck table, the flexible member comprises a lower portion engaged with the chuck table and an upper portion connected to the lower portion, an acute angle is between a lower surface of the upper portion and an upper surface of the lower portion facing and separated from the lower surface of the upper portion; and forming a vacuum seal between the semiconductor substrate and the chuck table by using the flexible member serving as a sealing ring, wherein when forming the vacuum seal, the upper portion of the flexible member is changed from a position higher than the carrying surface to a position substantially leveled with the carrying surface.

In accordance with some embodiments, a method for handling a semiconductor substrate includes: providing a semiconductor substrate, wherein the semiconductor substrate is warped with an edge portion higher than a central portion; placing the semiconductor substrate over a carrying surface of a chuck table of a semiconductor apparatus, where a first flexible member of the semiconductor apparatus is disposed in a first recess provided within the carrying surface of the chuck table, and the first flexible member comprises a lower portion comprising opposing sidewalls and a bottom surface that are in contact with inner surfaces of the chuck table; and an upper portion comprising a fixed end and a free end, wherein an included angle between the free end and the lower portion is an acute angle, the fixed end is connected to the lower portion and in contact with the chuck table, and the free end is positioned opposite the fixed end; and forming a vacuum seal between the semiconductor substrate and the chuck table, wherein when forming the vacuum seal, the semiconductor substrate presses against the upper portion of the first flexible member.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for handling a semiconductor substrate, comprising:
placing a semiconductor substrate over a semiconductor apparatus, wherein:
a central portion of the semiconductor substrate overlies a carrying surface of a chuck table of the semiconductor apparatus, an edge portion of the semiconductor substrate overlies a top surface of a first flexible member of the semiconductor apparatus,
the first flexible member is disposed within a recess of the chuck table and extends along a perimeter of the carrying surface, and a gap forms among the semiconductor substrate, the carrying surface of the chuck table, and the top surface of the first flexible member; and
introducing a vacuum in vacuum holes in the chuck table to form a vacuum seal among the semiconductor substrate, the chuck table, and the first flexible member.

2. The method of claim 1, wherein the first flexible member comprises a first portion and a second portion connected to the first portion, the first portion extends along a direction parallel to the carrying surface and comprises opposing sidewalls physically connected to inner sidewalls of the chuck table, the second portion comprises a top surface protruded from the recess before forming the vacuum seal.

3. The method of claim 2, wherein after forming the vacuum seal, the first flexible member is compressed as the semiconductor substrate presses against the top surface of the second portion of the first flexible member.

4. The method of claim 2, wherein an angle between the first portion and the second portion of the first flexible member reduces when forming the vacuum seal.

5. The method of claim 1, wherein when introducing the vacuum in the vacuum holes in the chuck table:
contacting the central portion of the semiconductor substrate with the carrying surface of the chuck table to form a seal between the semiconductor substrate and the carrying surface; and
deforming the first flexible member by pressing the edge portion of the semiconductor substrate against the first flexible member through a downward force created by the vacuum to form the vacuum seal between the semiconductor substrate and the first flexible member.

6. The method of claim 1, wherein when introducing the vacuum in the vacuum holes in the chuck table:
flattening the semiconductor substrate; and
leveling the top surface of the first flexible member with the carrying surface of the chuck table.

7. The method of claim 1, wherein the vacuum holes are individually segregated from one another, and when introducing the vacuum in the vacuum holes in the chuck table:
decreasing an amount of warpage of the semiconductor substrate from the central portion to the edge portion.

8. The method of claim 1, wherein a passageway is in the chuck table and connected to a vacuum source, each of the vacuum holes extends between the carrying surface of the chuck table and the passageway, during introducing the vacuum in the vacuum holes in the chuck table,
creating a suction force through the vacuum holes and the passageway, wherein the suction force pulls the semiconductor substrate against the carrying surface of the chuck table in a downward direction.

9. The method of claim 1, wherein the chuck table further comprises slot openings recessed from the carrying surface and in communication with the vacuum holes, second flexible members of the semiconductor apparatus are disposed within the slot openings and surround the vacuum holes, and during introducing the vacuum in the vacuum holes in the chuck table, the second flexible members are compressed as the semiconductor substrate presses against the second flexible members.

10. The method of claim 9, wherein each of the second flexible members comprises an upper portion connected to the semiconductor substrate and a lower portion connected to the upper portion and the chuck table, an angle between the upper portion and the lower portion of each of the second flexible member reduces when forming the vacuum seal.

11. A method for handling a semiconductor substrate, comprising:
placing a semiconductor substrate over a carrying surface of a chuck table of a semiconductor apparatus, wherein:
the semiconductor apparatus comprises the chuck table comprising vacuum holes extending from the carrying surface, and a flexible member extending along a periphery of the chuck table,
the flexible member comprises a lower portion engaged with the chuck table and an upper portion connected to the lower portion, an acute angle is between a lower surface of the upper portion and an upper surface of the lower portion facing and separated from the lower surface of the upper portion; and
forming a vacuum seal between the semiconductor substrate and the chuck table by using the flexible member serving as a sealing ring, wherein when forming the vacuum seal, the upper portion of the flexible member is changed from a position higher than the carrying surface to a position substantially leveled with the carrying surface.

12. The method of claim 11, wherein after placing the semiconductor substrate over the carrying surface of the chuck table, an edge portion of the semiconductor substrate is in contact with the upper portion of the flexible member, and a central portion of the semiconductor substrate is in contact with the carrying surface of the chuck table.

13. The method of claim 11, further comprising:
providing the semiconductor substrate, wherein the semiconductor substrate is warped with a central portion of the semiconductor substrate lower than an edge portion of the semiconductor substrate.

14. The method of claim 11, wherein the acute angle of the flexible member reduces when forming the vacuum seal.

15. The method of claim 11, wherein a passageway is in the chuck table and in communication with each of the vacuum holes, forming the vacuum seal comprises:
applying a suction force through the passageway and the vacuum holes to pull the semiconductor substrate.

16. A method for handling a semiconductor substrate, comprising:
providing a semiconductor substrate, wherein the semiconductor substrate is warped with an edge portion higher than a central portion;
placing the semiconductor substrate over a carrying surface of a chuck table of a semiconductor apparatus, wherein a first flexible member of the semiconductor apparatus is disposed in a first recess provided within the carrying surface of the chuck table, and the first flexible member comprises:
a lower portion comprising opposing sidewalls and a bottom surface that are in contact with inner surfaces of the chuck table; and
an upper portion comprising a fixed end and a free end, wherein an included angle between the free end and the lower portion is an acute angle, the fixed end is connected to the lower portion and in contact with the chuck table, and the free end is positioned opposite the fixed end; and
forming a vacuum seal between the semiconductor substrate and the chuck table, wherein when forming the vacuum seal, the semiconductor substrate presses against the upper portion of the first flexible member.

17. The method of claim 16, wherein when placing the semiconductor substrate over the carrying surface of the chuck table, the free end of the upper portion of the first flexible member is in contact with the edge portion of the semiconductor substrate.

18. The method of claim 16, wherein when placing the semiconductor substrate over the carrying surface of the chuck table, the carrying surface of the chuck table is in contact with the central portion of the semiconductor substrate.

19. The method of claim 16, wherein:
a passageway is in the chuck table and extends in a direction substantially parallel to the carrying surface, and vacuum holes extend between the carrying surface and the passageway,
when forming the vacuum seal, a suction force is applied through the passageway and the vacuum holes.

20. The method of claim 16, wherein:
the chuck table further comprises second recesses arranged along a perimeter of the carrying surface and surrounded by the first recess, and second flexible members of the semiconductor apparatus are disposed in the second recesses in a one-to-one correspondence,
when forming the vacuum seal, the second flexible members are compressed by the semiconductor substrate.
